(19) United States
(12) Patent Application Publication
(10) Pub. No.: US 2005/0052372 A1
(43) Pub. Date: Mar. 10, 2005

(54) [DISPLAY UNIT OF AN ACTIVE-MATRIX ORGANIC LIGHT EMITTING DISPLAY]

(76) Inventors: Hsin-Hung Lee, Taipei (TW); Tiao-Hung Hsiao, Kaohsiung (TW); Yun-Sheng Chen, Kaohsiung (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/605,807

(22) Filed: Oct. 28, 2003

(30) Foreign Application Priority Data
Aug. 20, 2003 (TW) 92122813

(51) Int. Cl. G09G 3/32

(52) U.S. Cl. 345/82

(57) ABSTRACT

A display unit of an active-matrix organic light emitting display is provided. The display unit includes a first transistor, a second transistor, and an organic light emitting diode. The display unit uses a P-type LTPS-TFT having a lower threshold voltage to reduce the operational Vgs. Therefore, the second transistor can provide the stable drain current for the organic light emitting diode. The organic light emitting diode can thus maintain its brightness for a longer period of time.

### CROSS REFERENCE TO RELATED APPLICATIONS

This application claims the priority benefit of Taiwan application serial no. 92122813, filed on Aug. 20, 2003.

### BACKGROUND OF INVENTION

1. Field of the Invention

This invention generally relates to a display unit of a display, and more particularly to a display unit of an active-matrix organic light emitting display (AM-OLED).

2. Description of the Related Art

The organic light emitting displays initially were passively driven. Currently the organic light emitting technology is being developed towards actively driven organic light emitting displays (OLED). This is because the lifetime of the passively driven OLED will decrease seriously as the size and the resolution of the display increase, which is the major difference from thin film transistor liquid crystal display (TFT-LCD). An actively driven TFT-LCD determines its gray level based on the voltage applied to the liquid crystal. A pixel in an array circuit of a TFT-LCD includes a thin film transistor and a capacitor. The purpose of the thin film transistor is for turning on/off. Hence, it is not required to have strictly uniform characteristics among the thin film transistors in the array circuit. For an active driven OLED, because it is driven by currents, the uniform characteristics of the organic light emitting diode will affect the uniformity of the display because it is difficult to control the uniformity due to the laser annealing process in low temperature polysilicon (LTPS) TFT technology.

FIG. 3 is a circuit of a conventional display unit of an active-matrix organic light emitting display (AM-OLED). In FIG. 3, the display unit 300 of an AM-OLED includes a first transistor 310, a second transistor 320, and an organic light emitting diode 330. The first transistor 310 and the second transistor 320 are P-type LTPS-TFT, N-type LTPS-TFT, or α-silicon TFT.

The conventional display unit 300 of an AM-OLED operates as follows. The first transistor 310 receives the address signal from the gate driver circuit and determines whether or not to turn on based on the address signal. If the first transistor 310 is turned on, the first transistor 310 will send the display signal to the gate of the second transistor 320. The second transistor 320 is turned on to supply current to the organic light emitting diode 330 after it receives the display signal. The organic light emitting diode 330 emits the light after it receives the current from the drain of the second transistor 320.

Among those three aforementioned TFTs, the P-type LTPS-TFT has a higher threshold voltage so that it requires a higher Vgd (voltage between the gate and the drain) during the operation mode. Hence, the electrons and holes of the P-type LTPS-TFT are affected by the high Vgd to impact the Si-H bond, which causes the drain current supplied to the organic light emitting diode 330 to attenuate seriously after a period of time. Hence, the brightness of the organic light emitting diode 330 will decrease after that period of time.

FIG. 4 is a normalized drain current-time curve of a conventional AM-OLED. In FIG. 4, the ordinate represents normalized drain current of a P-type LTPS-TFT; the initial drain current is 2 mA. After 1200-hr use of the P-type LTPS-TFT, the drain current reduces by 40%, which means the decrease of the brightness of the organic light emitting diode.

In light of the above, because the convention display unit of an AM-OLED uses the P-type LTPS-TFTs having a higher threshold voltage, the brightness of the organic light emitting diode will reduce due to the decrease of the drain current.

### SUMMARY OF INVENTION

An object of the present invention is to provide a display unit of an AM-OLED to reduce the threshold voltage of the P-type LTPS-TFT and thus reduce the operational Vgd, so that the drain current supplied to the P-type LTPS-TFT can be stable for a longer period of time.

The present invention provides a display unit of an active-matrix organic light emitting display comprising: a first transistor, a second transistor and an organic light emitting diode.

In a preferred embodiment of the present invention, the first transistor has a gate for receiving a first driving signal. The first transistor determines whether or not to conduct a second signal based on the first driving signal. The first transistor is a P-type transistor having a threshold voltage, and the absolute value of the threshold voltage of the first transistor is between 2V to 5V.

In a preferred embodiment of the present invention, the second transistor has a gate for receiving the second signal. The second transistor determines whether or not to conduct a power source based on the second signal. The second transistor is a P-type transistor having a threshold voltage, and the absolute value of the threshold voltage of the second transistor is between 2V to 5V.

In a preferred embodiment of the present invention, the organic light emitting diode receives the power source to emit a light after the second signal turns on the second transistor.

The present invention uses a P-type LTPS-TFT having a lower threshold voltage. Hence, the operational Vgd can be reduced under the same drain current thereby providing the P-type LTPS-TFT with the stable drain current for a longer period of time, which keeps the brightness of the organic light emitting diode.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF DRAWINGS

FIG. 1 is a circuit of a display unit of an active-matrix organic light emitting display in accordance with the first embodiment of the present invention.

FIG. 2 is a normalized drain current-time curve of an active-matrix organic light emitting display in accordance with the first embodiment of the present invention.

FIG. 3 is a circuit of a conventional display unit of an active-matrix organic light emitting display.

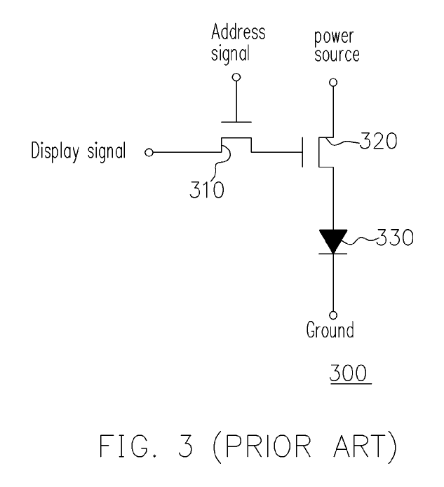

FIG. 4 is a normalized drain current-time curve of a conventional active-matrix organic light emitting display.

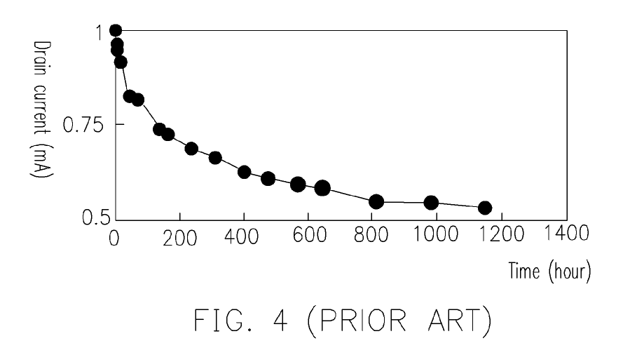

### DETAILED DESCRIPTION

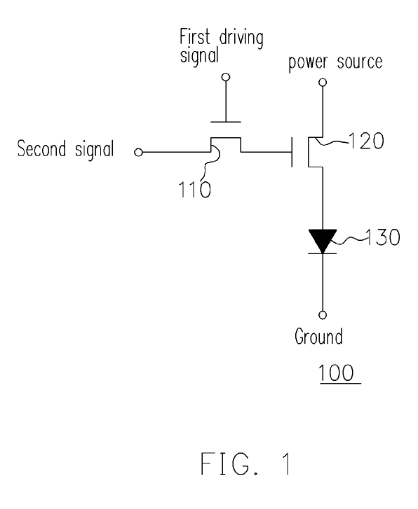

FIG. 1 is a circuit of a display unit of an active-matrix organic light emitting display in accordance with the first embodiment of the present invention. Referring to FIG. 1, a display unit 100 of an active-matrix organic light emitting display comprises a first transistor 110, a second transistor 120, and an organic light emitting diode 130. The first transistor 110 is coupled to the first driving signal, the gate of the second transistor 120. The second transistor 120 is coupled to the power source and the input of the organic light emitting diode 130. The organic light emitting diode 130 is coupled to the ground.

The first and second transistors 110 and 120 can be P-type LTPS-TFTs. The first driving signal can be, but not limited to, the address signal generated by the gate driving circuit (not shown). The second signal can be, but not limited to, the display signal generated by the data driving circuit (not shown).

In this embodiment, the display unit 100 operates as follows. The first transistor 110 receives the first driving signal. The first transistor 110 determines whether or not to conduct the second signal based on the first driving signal. When the first driving signal turns on the first transistor 110, the second signal will be conducted to the gate of the second transistor. The second transistor 120 is then turned on. Hence the power source coupled to the second transistor 120 can be supplied to the organic light emitting diode 130. The organic light emitting diode 130 thus emits light after receiving the current from the power source. The drain current Id supplied by the power source to the second transistor 120 is expressed by the following expression, wherein Cᵢ represents the gate capacitor per unit area; W represents the width of the channel of the transistor; L represents the length of the channel of the transistor; p represents the mobile rate of the electrons; Vgs represents the voltage between the gate and the source; Vth represents the threshold voltage.

$${I}_{d} = \frac{1}{2} {C}_{i} μ \frac{W}{L} {( {V}_{gs} - {V}_{th} )}^{2}$$

In the above equation, the factors affecting the drain current I_{d} include W, L, Vgs, and Vth. The manufacturers of the TFT-LCD have tried to change the width or length of the transistor channel to compensate the reduced I_{d}. The present invention, unlike the conventional method, reduces the threshold voltage Vth so that the operational Vgs is reduced under the same I_{d}. By reducing Vgs, it can reduce the possibility that the electrons or holes impact the Si-H bonds. In this embodiment, the absolute value of the threshold voltage of the first transistor 110 and the second transistor 120 is between 2V-5V and preferably between 2.5V-3.5V.

In the preferred embodiment of the present invention, the decrease of the threshold voltage can alleviate the impact of Vgs on the electrons and holes in the second transistor 120. Hence, the second transistor 120 can provide the stable drain current for the organic light emitting diode 130. The organic light emitting diode 130 can thus maintain its brightness for a longer period of time.

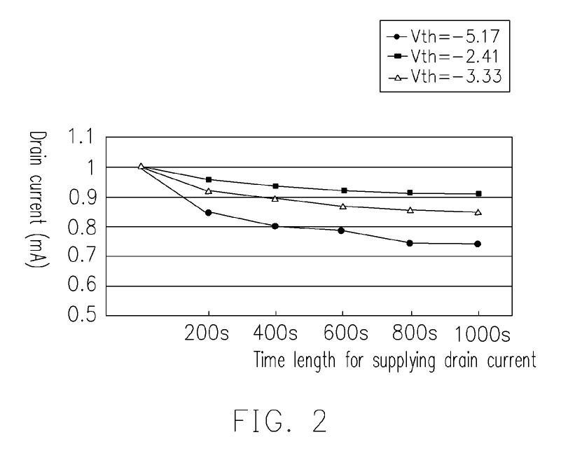

FIG. 2 is a normalized drain current-time curve of an active-matrix organic light emitting display in accordance with the first embodiment of the present invention. Referring to FIG. 2, the ordinate represents the normalized drain current; the abscissa represents the time length for supplying the drain current. The curve presented by a series of black dots represents a display unit using a P-type LTPS-TFT having a threshold voltage of −5.17V. The curve presented by a series of black squares represents a display unit using a P-type LTPS-TFT having a threshold voltage of −3.33V. The curve presented by a series of hollow triangles represents a display unit using a P-type LTPS-TFT having a threshold voltage of −2.41V. The gate voltages for those P-type LTPS-TFTs are −15V; the drain voltages are −12V; the source voltages are −2.83V, −4.63V, and −6.42V, respectively. Hence, the initial drain currents for those P-type LTPS-TFTs are 100 mA. The drain currents shown in FIG. 2 are normalized; the test period is 1000 seconds; the drain current is measured per 200 second.

In this embodiment, the lower the threshold voltage of the P-type LTPS-TFT, the smaller the attenuation of the drain current. That is, because the P-type LTPS-TFT has a lower threshold voltage, the operational Vgs can be reduced under the same drain current, which can reduce the possibility that the electrons or holes impact the Si-H bonds. Therefore, the P-type LTPS-TFT having a lower threshold voltage can provide the stable drain current for the organic light emitting diode.

In brief, the display unit of an active-matrix organic light emitting display of the present invention uses the P-type LTPS-TFT having a lower threshold voltage. Therefore, the P-type LTPS-TFT can provide the stable drain current for the organic light emitting diode. The organic light emitting diode can thus maintain its brightness for a longer period of time.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

1. A display unit of an active-matrix organic light emitting display, comprising:
a first transistor, having a gate for receiving a first driving signal, said first transistor determining whether or not to conduct a second signal based on said first driving signal;
a second transistor, having a gate for receiving said second signal, said second transistor determining whether or not to conduct a power source based on said second signal; and
an organic light emitting diode, receiving said power source to emit a light;
wherein said second transistor is a P-type transistor having a threshold voltage, and an absolute value of said threshold voltage of said second transistor is between 2V to 5V.

2. The display unit of claim 1, wherein the absolute value of said threshold voltage of said second transistor is between 2.5V to 3.5V.

3. The display unit of claim 1, wherein said first transistor is a P-type transistor having a threshold voltage, and the absolute value of said threshold voltage of said first transistor is between 2V to 5V.

4. The display unit of claim 3, wherein the absolute value of said threshold voltage of said first transistor is between 2.5V to 3.5V.
